(19) United States
(12) Patent Application Publication
(10) Pub. No.: US 2007/0126097 A1
(43) Pub. Date: Jun. 7, 2007

(54) Chip package structure

(76) Inventor: Chun-Hung Lin, Tainan County (TW)

Correspondence Address: J.C. Patents, Inc.;Suite 250, 4 Venture, Irvine, CA, 92618, US

(21) Appl. No.: 11/373,531

(22) Filed: Mar. 9, 2006

(30) Foreign Application Priority Data
Dec. 7, 2005 (TW) 94143093

(51) Int. Cl. H01L 23/02

(52) U.S. Cl. 257/678

(57) ABSTRACT

A chip package structure including a first chip, a circuit substrate, and a two-stage thermosetting adhesive layer is provided. The first chip has a first upper surface, a first side surface, and a first bottom surface. The circuit substrate has an upper surface and a bottom surface. The first chip is electrically connected to the circuit substrate. The two-stage thermosetting adhesive layer is located on the upper surface of the substrate and has a first adhesive surface and a second adhesive surface. Part of the first adhesive surface is bonded to the first bottom surface and the second adhesive surface is bonded to the upper surface of the substrate such that the first chip is adhered to the upper surface of the substrate. The first adhesive surface is substantially parallel to the second adhesive surface, and the two-stage thermosetting adhesive layer has a tapered edge.

### CROSS-REFERENCE TO RELATED APPLICATION

This application claims the priority benefit of Taiwan application serial no. 094143093, filed on Dec. 7, 2005. All disclosure of the Taiwan application is incorporated herein by reference.

### BACKGROUND OF THE INVENTION

1. Field of Invention

The present invention relates to a semiconductor device. More particularly, the present invention relates to a chip package structure.

2. Description of Related Art

Among the semiconductor industry, the production of integrated circuits (IC) can be mainly divided into three phases: wafer fabrication, IC fabrication and IC package. The chip is fabricated through steps such as wafer fabrication, circuit design, mask fabrication and wafer slicing. And, after being electrically connected with external signal through the bonding pad located on the chip, each chip formed by wafer slicing can be encapsulated by an encapsulant material. The purpose of the encapsulation is to avoid the chip from being dampened, heated, and interrupted by noise signal, and to provide a medium for electrically connecting the chip with the external circuit, so as to complete the step of encapsulating IC.

Referring to FIG. 1, FIG. 1 is a cross-sectional diagram of a conventional chip package structure. The conventional chip package structure 100 includes a chip 110, a circuit substrate 120, an adhesive layer 130, a plurality of bonding wires 140 and an encapsulant 150. Specifically, the chip 110 is adhered to the circuit substrate 120 by the adhesive layer 130, and the material of the adhesion layer 130 is, for example, epoxy resin. A plurality of bonding pads located on the upper surface 112 of the chip 110 are electrically connected with the circuit substrate 120 through the bonding wires 140. In addition, the encapsulant 150 encapsulates the chip 110, the adhesive layer 130 and the bonding wires 140. The function of the encapsulant 150 is to protect the bonding wires 140 from being impacted by outside humidity, heat and noise signal.

In detail, when the chip 110 is adhered to the circuit substrate 120 by heating and pressurizing the adhesive layer 130, as the epoxy resin is fluid and has fluidity, the adhesive layer 130 may appear anomalous figuration when being pressurized, and creep phenomenon occurs at the side surface 116 of the chip 110 because of the capillarity of the adhesive layer 130. The creep phenomenon may be different as along as the different adhesion of the material of the adhesive layer 130.

However, when the chip 110 is adhered to the circuit substrate 120 by the adhesive layer 130, the adhesive layer 130 still has fluidity, therefore, pressing the adhesive layer 130 may cause the adhesive layer 130 to flow to other areas of the circuit substrate 120 so as to contaminate the area where the circuit substrate 120 is electrically connected with the bonding wires 140, so that the yield of the package is compromised. Moreover, after the circuit substrate 120 is pre-coated with the adhesive layer 130, the circuit substrate 120 coated with the adhesive layer 130 can not be shipped or stored in stack. The chip 110 must be adhered on the circuit substrate 120 as soon as possible, or the circuit substrate 120 may be contaminated or attached with foreign objects resulting in failure of the packaging fabrication.

Referring to FIG. 2, FIG. 2 is a cross-sectional diagram of another conventional chip package structure. In order to eliminate the above problems, another conventional chip package structure 200 is provided. The difference between the chip package structure 200 and the chip package structure 100 is that: the chip 210 in the chip package structure 200 is adhered to the circuit substrate 220 by a tape 230. As the tape is pre-cut to stick on the circuit substrate 220, when the chip 210 is adhered to the circuit substrate 220 by the tape 230, the tape 230 can still keep regular edge on the outside surface apart from the chip 210, i.e., keep the edge figuration as pre-cut even undergoing the compression process. Besides, the tape 230 would not overflow to other areas of the circuit substrate 220 to further contaminate the area where the circuit substrate 220 is electrically connected with the bonding wires.

However, after the tape 230 is adhered to the circuit substrate 220, the circuit substrate 220 with tape 230 still can not be shipped or stored in stack. The chip 210 must be adhered on the circuit substrate 220 as soon as possible, or the circuit substrate 220 may be contaminated or attached by foreign objects resulting in failure of the packaging fabrication. As described, it is apparent that to improve the conventional chip package structure and the package fabrication are indeed necessary.

### SUMMARY OF THE INVENTION

Accordingly, the present invention is directed to provide a chip package structure to resolve the problem that the adhesive layer overflows to contaminate the area where the bonding wires are electrically connected.

Another aspect of the present invention is to provide a chip package structure to resolve the problem that the circuit substrate with adhesive layer can not be shipped or stored in stack.

In order to achieve the above and other aspects, the present invention provides a chip package structure including a first chip, a circuit substrate, and a two-stage thermosetting adhesive layer. The first chip has a first upper surface, a first side surface, and a first bottom surface. The circuit substrate has an upper surface and a bottom surface. The first chip is electrically connected to the circuit substrate. Moreover, the two-stage thermosetting adhesive layer is located on the upper surface of the substrate and has a first adhesive surface and a second adhesive surface. Part of the first adhesive surface is bonded to the first bottom surface and the second adhesive surface is bonded to the upper surface of the substrate, such that the first chip is adhered to the upper surface of the substrate. The first adhesive surface is substantially parallel to the second adhesive surface, and the two-stage thermosetting adhesive layer has a tapered edge.

According to one embodiment of the present invention, the first chip includes a plurality of bonding pads located on the first upper surface.

According to one embodiment of the present invention, the first chip includes a plurality of bonding pads located on the first upper surface. Moreover, the chip package structure further includes a plurality of bonding wires, wherein at least one of the bonding pads is electrically connected with the upper surface of the substrate through at least one of the bonding wires.

According to one embodiment of the present invention, the first chip includes a plurality of bonding pads located on the first upper surface. Moreover, the chip package structure further includes a plurality of bonding wires, wherein at least one of the bonding pads is electrically connected with the surface of the substrate through at least one of the bonding wires. In addition, the chip package structure further includes an encapsulant which encapsulates at least the first chip and the bonding wires.

According to one embodiment of the present invention, the chip package structure further includes a second chip and an adhesive layer. The second chip has a second upper surface, a second bottom surface and a plurality of bonding pads located on the second upper surface. The second chip is electrically connected to the circuit substrate. The adhesive layer is located between the first chip and the second chip, wherein the second bottom surface of the second chip is bonded to the first upper surface of the first chip.

According to one embodiment of the present invention, the chip package structure further includes a second chip and an adhesive layer. The second chip has a second upper surface, a second bottom surface and a plurality of bonding pads located on the second upper surface. The adhesive layer is located between the first chip and the second chip, wherein the second bottom surface of the second chip is bonded to the first upper surface of the first chip. Moreover, the material of the adhesive layer may be the same as that of the two-stage thermosetting adhesive layer.

According to one embodiment of the present invention, the chip package structure further includes a second chip and an adhesive layer. The second chip has a second upper surface, a second bottom surface and a plurality of bonding pads located on the second upper surface. The adhesive layer is located between the first chip and the second chip, wherein the second bottom surface of the second chip is bonded to the first upper surface of the first chip. Moreover, the chip package structure further includes a plurality of bonding wires, and at least one of the bonding pads is electrically connected with the upper surface of the substrate through at least one of the bonding wires.

According to one embodiment of the present invention, the chip package structure further includes a second chip and an adhesive layer. The second chip has a second upper surface, a second bottom surface and a plurality of bonding pads located on the second upper surface. The adhesive layer is disposed between the first chip and the second chip, wherein the second bottom surface of the second chip is bonded to the first upper surface of the first chip. Moreover, the chip package structure further includes a plurality of bonding wires, and at least one of the bonding pads is electrically connected with the upper surface of the substrate through at least one of the bonding wires. In addition, the chip package structure further includes an encapsulant which at least encapsulates the first chip, the second chip and the bonding wires.

According to one embodiment of the present invention, the circuit substrate has a through hole.

According to one embodiment of the present invention, the circuit substrate includes a through hole. Moreover, the two-stage thermosetting adhesive layer is, for example, located in the surrounding area of the through hole.

According to one embodiment of the present invention, the circuit substrate has a through hole. Moreover, the first chip includes a plurality of bonding pads located on the first bottom surface, and the through hole exposes the bonding pads.

According to one embodiment of the present invention, the circuit substrate has a through hole. Moreover, the first chip includes a plurality of bonding pads located on the first bottom surface, and the through hole exposes the bonding pads. In addition, the chip package structure further includes a plurality of bonding wires, wherein each bonding pad is electrically connected with the bottom surface of the substrate through at least one of the bonding wires, and the bonding wires pass through the through hole.

According to one embodiment of the present invention, the circuit substrate has a through hole. Moreover, the first chip includes a plurality of bonding pads located on the first bottom surface, and the through hole exposes the bonding pads. In addition, the chip package structure further includes a plurality of bonding wires, wherein each bonding pad is electrically connected with the bottom surface of the substrate through at least one of the bonding wires, and the bonding wires pass through the through hole. Moreover, the chip package structure further includes an encapsulant which fills the through hole to encapsulate at least the first chip and the bonding wires.

According to one embodiment of the present invention, the two-stage thermosetting adhesive layer further includes a ringlike protruding portion surrounding the first side surface, and the first side surface is bonded to the ringlike protruding portion while a top surface of the ringlike protruding portion adjacent to the first side surface is substantially perpendicular to the first side surface.

According to one embodiment of the present invention, the two-stage thermosetting adhesive layer includes a solvent type two-stage thermosetting adhesive layer or a non-solvent type two-stage thermosetting adhesive layer.

According to one embodiment of the present invention, the material of the two-stage thermosetting adhesive layer includes polyimide, benzocyclobutene (BCB), or polyquinolin.

According to one embodiment of the present invention, the two-stage thermosetting adhesive layer includes an UV-curing type two-stage thermosetting adhesive layer or a thermal-curing type two-stage thermosetting adhesive layer.

In order to achieve the above and other aspects, the present invention provides a chip package structure which includes a first chip, a second chip, a two-stage thermosetting adhesive layer, and a circuit substrate. The first chip has a first upper surface, a first side surface, and a first bottom surface. The second chip has a second upper surface, a second side surface, and a second bottom surface. Moreover, the two-stage thermosetting adhesive layer is located between the first chip and the second chip, wherein the two-stage thermosetting adhesive layer has a first adhesive surface and a second adhesive surface. At least part of the first adhesive surface is bonded to the second bottom surface and at least part of the second adhesive surface is bonded to the first upper surface such that the second chip is adhered to the upper surface of the first chip. The first adhesive surface is substantially parallel to the second adhesive surface and the two-stage thermosetting adhesive layer has a tapered edge. In addition, the circuit substrate has an upper surface and a bottom surface. The first chip is disposed on the upper surface of the substrate, and the first chip and the second chip are electrically connected with the circuit substrate, respectively.

According to one embodiment of the present invention, the chip package structure further includes an adhesive layer disposed between the first chip and the circuit substrate, wherein the first bottom surface of the first chip is bonded to the upper surface of the substrate of the circuit substrate by the adhesive layer.

According to one embodiment of the present invention, the first chip includes a plurality of first bonding pads located on the first upper surface, and the second chip includes a plurality of second bonding pads located on the second upper surface.

According to one embodiment of the present invention, the first chip includes a plurality of first bonding pads located on the first upper surface, and the second chip includes a plurality of second bonding pads located on the second upper surface. Moreover, the chip package structure further includes a plurality of first bonding wires and a plurality of second bonding wires. At least one of the first bonding pads is electrically connected with the upper surface of the substrate through at least one of the first bonding wires, and at least one of the second bonding pads is electrically connected with the upper surface of the substrate through at least one of the second bonding wires.

According to one embodiment of the present invention, the first chip includes a plurality of first bonding pads located on the first upper surface, and the second chip includes a plurality of second bonding pads located on the second upper surface. Moreover, the chip package structure further includes a plurality of first bonding wires and a plurality of second bonding wires. At least one of the first bonding pads is electrically connected with the upper surface of the substrate through at least one of the first bonding wires, and at least one of the second bonding pads is electrically connected with the upper surface of the substrate through at least one of the second bonding wires. In addition, the chip package structure further includes an encapsulant which at least encapsulates the first and the second chips, the first and the second bonding wires.

According to one embodiment of the present invention, the first chip includes a plurality of first bonding pads located on the first bottom surface, and the second chip includes a plurality of second bonding pads located on the second upper surface.

According to one embodiment of the present invention, the first chip includes a plurality of first bonding pads located on the first bottom surface, and the second chip includes a plurality of second bonding pads located on the second upper surface. Moreover, the chip package structure further includes a plurality of bonding wires and a plurality of solder bumps. At least one of the second bonding pads is electrically connected with the upper surface of the substrate through at least one of the bonding wires, and each first bonding pad is electrically connected with the upper surface of the substrate through one of the solder bumps.

According to one embodiment of the present invention, the first chip includes a plurality of first bonding pads located on the first bottom surface, and the second chip includes a plurality of bonding pads located on the second upper surface. Moreover, the chip package structure further includes a plurality of bonding wires and a plurality of solder raised portion. At least one of the second bonding pads is electrically connected with the upper surface of the substrate through at least one of the bonding wires, and each first bonding pad is electrically connected with the upper surface of the substrate through one of the solder bumps. In addition, the chip package structure further includes an encapsulant, which encapsulates at least the first and the second chips, the bonding wires and the folder raised portion.

According to one embodiment of the present invention, the two-stage thermosetting adhesive layer further includes a ringlike protruding portion, surrounding the first side surface, and the first side surface is bonded to the ringlike protruding portion while a top surface of the ringlike protruding portion adjacent to the first side surface is substantially perpendicular to the first side surface.

According to one embodiment of the present invention, the two-stage thermosetting adhesive layer further includes a ringlike protruding portion, surrounding the second side surface, and the second side surface is bonded to the ringlike protruding portion while a top surface of the ringlike protruding portion adjacent to the second side surface is substantially perpendicular to the second side surface.

According to one embodiment of the present invention, the two-stage thermosetting adhesive layer includes a solvent type two-stage thermosetting adhesive layer or a non-solvent type two-stage thermosetting adhesive layer.

According to one embodiment of the present invention, the material of the two-stage thermosetting adhesive layer includes polyimide, benzocyclobutene (BCB), or polyquinolin.

According to one embodiment of the present invention, the two-stage thermosetting adhesive layer includes an UV-curing type two-stage thermosetting adhesive layer or a thermal-curing type two-stage thermosetting adhesive layer.

According to the above mentioned, as the two-stage thermosetting adhesive layer of the chip package structure of the present invention can be pre-cured into solid or gel B-stage thermosetting adhesive layer, in the subsequent fabricating processes to compress the chip onto the circuit substrate or compress the chip onto another chip, the two-stage thermosetting adhesive layer will not overflow to other areas of the circuit substrate or to another chip, so as to achieve the object of preventing the area where the circuit substrate or another chip is electrically connected with the bonding wires from being contaminated. Moreover, as the two-stage thermosetting adhesive layer of the chip package structure of the present invention can be pre-cured into solid or B-stage thermosetting adhesive layer which has no adhesion at room temperature, the circuit substrate or the chip with spread of the two-stage thermosetting adhesive layer can be shipped or stored in stack.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional diagram of a conventional chip package structure.

FIG. 2 is a schematic cross-sectional diagram of another conventional chip package structure.

FIG. 3 is a schematic cross-sectional diagram of a chip package structure according to the first embodiment of the present invention.

FIG. 4 is a schematic cross-sectional diagram of a chip package structure according to the second embodiment of the present invention.

FIG. 5 is a schematic cross-sectional diagram of a chip package structure according to the third embodiment of the present invention.

FIG. 6 is a schematic cross-sectional diagram of a chip package structure according to the fourth embodiment of the present invention.

FIG. 7 is a schematic cross-sectional diagram of a chip package structure according to the fifth embodiment of the present invention.

FIG. 8 is a schematic cross-sectional diagram of a chip package structure according to the sixth embodiment of the present invention.

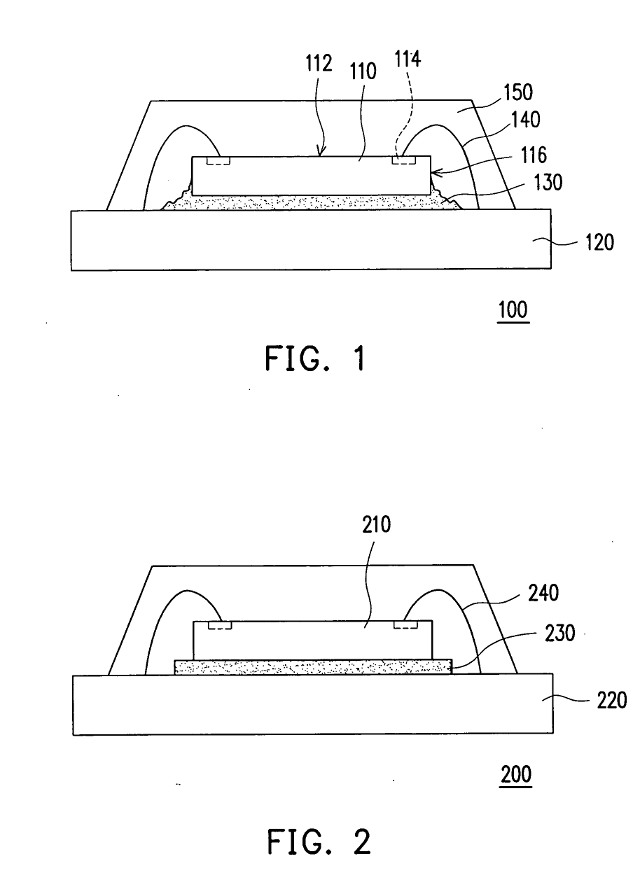

### DESCRIPTION OF EMBODIMENTS

### The First Embodiment

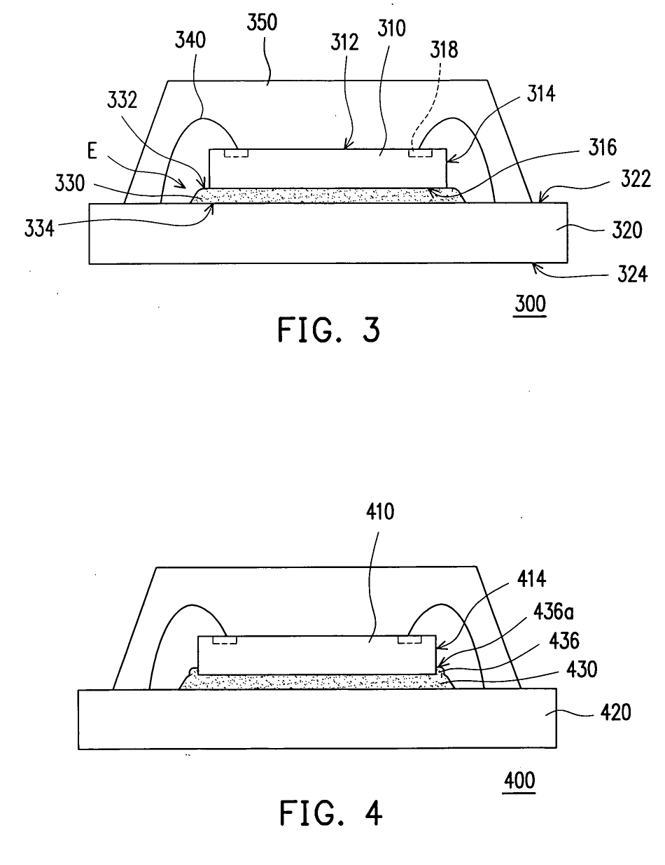

Referring to FIG. 3, FIG. 3 is a schematic cross-sectional diagram of a chip package structure according to the first embodiment of the present invention. The chip package structure 300 in the first embodiment includes a first chip 310, a circuit substrate 320, and a two-stage thermosetting adhesive layer 330. The first chip 310 has a first upper surface 312, a first side surface 314, and a first bottom surface 316. The circuit substrate 320 has an upper surface 322 of the substrate and a bottom surface 324 of the substrate. The first chip 310 is electrically connected to the circuit substrate 320. Moreover, the two-stage thermosetting adhesive layer 330 is located on the upper surface 322 of the substrate and has a first adhesive surface 332 and a second adhesive surface 334. Part of the first adhesive surface 332 is bonded to the first bottom surface 316 and the second adhesive surface 334 is bonded to the upper surface 322 of the substrate such that the first chip 310 is adhered to the upper surface 322 of the circuit substrate 320. The first adhesive surface 332 is substantially parallel to the second adhesive surface 334 and the two-stage thermosetting adhesive layer 330 has a tapered edge E.

In the first embodiment, the first chip 310 includes a plurality of bonding pads 318 located on the first upper surface 312. Moreover, the chip package structure 300 further includes a plurality of bonding wires 340 and an encapsulant 350. At least one of the bonding pads 318 is electrically connected with the upper surface 322 of the substrate through at least one of the bonding wires 340, and the encapsulant 350 encapsulates at least the first chip 310 and the bonding wires 340. The function of the encapsulant 350 is to protect the bonding wires from being impacted by the outside humidity, heat and noise signal, and the encapsulant 350 can hold the bonding wires 340 and provide the structure for hand holding.

In the first embodiment, the two-stage thermosetting adhesive layer 330 includes a solvent type two-stage thermosetting adhesive layer or a non-solvent type two-stage thermosetting adhesive layer; and the difference between them is that: the solvent type can improve the fluidity of the two-stage thermosetting adhesive layer 330, and the material of the two-stage thermosetting adhesive layer 330 includes polyimide, benzocyclobutene (BCB), or polyquinolin. In addition, the two-stage thermosetting adhesive layer 330 includes an UV-curing type two-stage thermosetting adhesive layer or a thermal-curing type two-stage thermosetting adhesive layer, which can be cured by ultraviolet radiation or by heating, respectively.

The following will describe in detail the fabrication process of adherence of the first chip 310 to the upper surface 322 of the substrate of the circuit substrate 320 by the two-stage thermosetting adhesive layer 330. First, the two-stage thermosetting adhesive layer 330 spreads on the upper surface 322 of the substrate; at this time, the two-stage thermosetting adhesive layer 330 is an A-stage thermosetting adhesive layer with fluidity characteristic, for example, liquid or glue. Moreover, the method of spreading the two-stage thermosetting adhesive layer 330 on the upper surface 322 of the substrate includes stenciling, painting, printing, spraying, spin-coating, or dipping, etc.

Next, the above mentioned circuit substrate 320 with spread of two-stage thermosetting adhesive layer 330 can be ultraviolet radiated or heated so that the two-stage thermosetting adhesive layer 330 can be pre-cured. At this time, the two-stage thermosetting adhesive layer 330 is a B-stage thermosetting adhesive layer which has solidity or gel characteristic and has no adhesion at room temperature. Therefore, the circuit substrate 320 can be shipped or stored in stack. Moreover, if the subsequent fabrication process of adhering the first chip 310 on the circuit substrate 320 is needed, the first chip 310 and the circuit substrate 320 can be ultraviolet radiated or heated again, so that the first chip 310 is adhered to the upper surface 322 of the substrate of the circuit substrate 320 again by the two-stage thermosetting adhesive layer 310. It can be learned from the above that in the compression process, the two-stage thermosetting adhesive layer 330 in the status of B-stage thermosetting adhesive layer would not overflow to other areas of the upper surface 322 of the substrate, which will contaminate the area where the upper surface 322 of the substrate is electrically connected with the bonding wires 340.

### The Second Embodiment

Referring to FIG. 4, FIG. 4 is a schematic cross-sectional diagram of a chip package structure according to the second embodiment of the present invention. The difference between the second embodiment and the first embodiment is that: the two-stage thermosetting adhesive layer 430 of the chip package structure 400 had different figuration. The two-stage thermosetting adhesive layer 430 further includes a ringlike protruding portion 436 surrounding the first side surface 414, and the first side surface 414 is bonded to the ringlike protruding portion 436 while a top surface 436a of the ringlike protruding portion 436 adjacent to the first side surface 414 is substantially perpendicular to the first side surface 414.

The formation of the ringlike protruding portion 436 is due to the processing period when the two-stage thermosetting adhesive layer 430 is pre-cured into B-stage thermosetting adhesive layer from A-stage thermosetting adhesive layer. If the time of a predefined high temperature (for example, 125° C.) is short and the partially cured degree of the two-stage thermosetting adhesive layer 430 converting into the B-stage thermosetting adhesive layer from A-stage thermosetting adhesive layer is low, when performing the subsequent fabricating process of compressing the first chip 410 to adhere the circuit substrate 420 by heating, the two-stage thermosetting adhesive layer 430 may form a ringlike protruding portion 436 resulting from the pressure, and the volume of the ringlike protruding portion 436 is big. It can be learned from the above that: provided other compression conditions are unchanged, the volume of the ring-like protruding portion 430 is related to the processing period when the two-stage thermosetting adhesive layer 430 is pre-cured into B-stage thermosetting adhesive layer status from A-stage thermosetting adhesive layer status, that is, the volume of the ringlike protruding portion 430 is related to the degree of partially cured two-stage thermosetting adhesive layer 430.

### The Third Embodiment

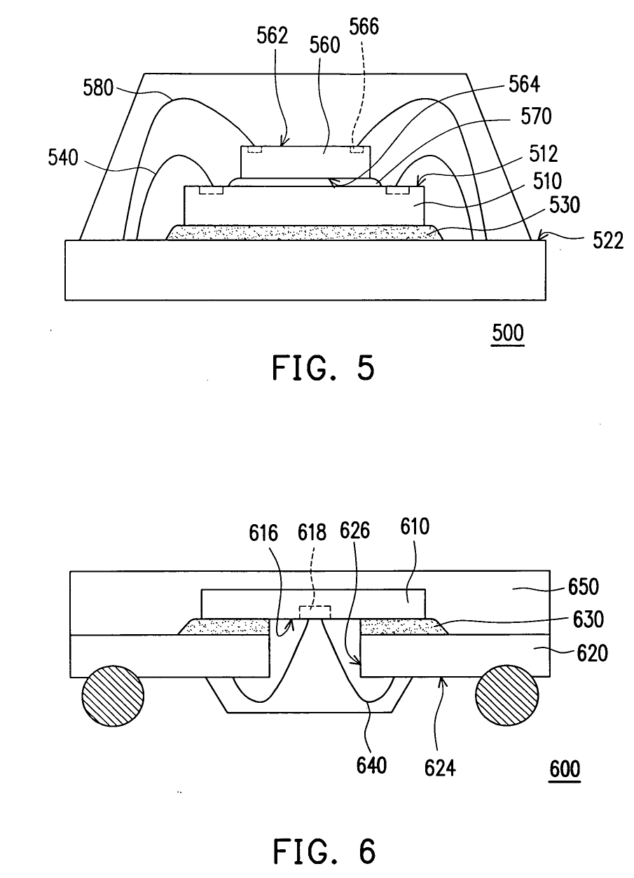

Referring to FIG. 5, FIG. 5 is a schematic cross-sectional diagram of a chip package structure according to the third embodiment of the present invention. The difference between the third embodiment and the above embodiments is that: the chip package structure 500 is a multiple chip package structure. The multiple chip package structure 500 further includes a second chip 560 and an adhesive layer 570. The second chip 560 has a second upper surface 562, a second bottom surface 564, and a plurality of bonding pads 566 located on the second upper surface 562. The material of the adhesive layer 570 may be the same as that of the two-stage thermosetting adhesive layer 530. The adhesive layer 570 is disposed between the first chip 510 and the second chip 560, wherein the second bottom surface 564 of the second chip 560 is bonded to the first upper surface 512 of the first chip 510. Moreover, the chip package structure 500 further includes a plurality of bonding wires 580, and at least one of the bonding pads 566 is electrically connected with the upper surface 522 of the substrate through at least one of the bonding wires 580. In addition, the chip package structure 500 further includes an encapsulant 550 which encapsulates at least the first chip 510, the second chip 560 and the bonding wires 540, 580.

It should be noted that, in the third embodiment, the two-stage thermosetting adhesive layer 530 may also have a ringlike protruding portion (not shown). And, the formation, figuration, location and connection relation are all the same as described in the second embodiment, therefore, the detail is omitted here.

### The Fourth Embodiment

Referring to FIG. 6, FIG. 6 is a schematic cross-sectional diagram of a chip package structure according to the fourth embodiment of the present invention. The difference between the fourth embodiment and the above embodiments is that: the circuit substrate 620 of the chip package structure 600 of the fourth embodiment has a through hole 626, and the two-stage thermosetting adhesive layer 630 is, for example, located in the surrounding area of the through hole 626. Moreover, the first chip 610 includes a plurality of bonding pads 618 located on the first bottom surface 616, and the through hole 626 exposes the bonding pads 618. In addition, the chip package structure 600 further includes a plurality of bonding wires 640, and each of the bonding pads 618 is electrically connected to the bottom surface 624 of the substrate through at least one of the bonding wires 640, and the bonding wires 640 pass through the through hole 626. And, the chip package structure 600 further includes an encapsulant 650 which fills in the through hole 626 to encapsulate at least the first chip 610 and the bonding wires 640. As seen from the above, the volume of the chip package structure 600 of the fourth embodiment can be less than that of the chip package structures 300, 400, 500 (as shown in FIG. 3, FIG. 4, and FIG. 5) in the abovementioned embodiments.

It should be noted that, in the fourth embodiment, the two-stage thermosetting adhesive layer 630 may also have a ringlike protruding portion (not shown). And, the formation, figuration, location and connection relation are all the same as described in the second embodiment, therefore, the detail is omitted here.

### The Fifth Embodiment

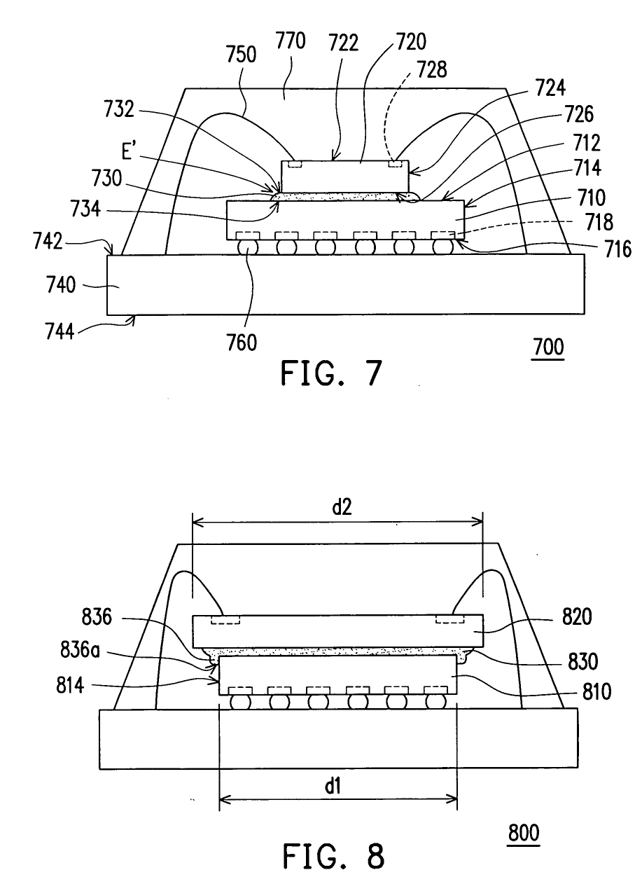

Referring to FIG. 7, FIG. 7 is a schematic cross-sectional diagram of a chip package structure according to the fifth embodiment of the present invention. The chip package structure 700 in the fifth embodiment is a multiple chip package structure, which includes a first chip 710, a second chip 720, a two-stage thermosetting adhesive layer 730 and a circuit substrate 740. The first chip 710 has a first upper surface 712, a first side surface 714 and a first bottom surface 716; and the second chip 720 has a second upper surface 722, a second side surface 724 and a second bottom surface 726.

Moreover, the two-stage thermosetting adhesive layer 730 is located between the first chip 710 and the second chip 720, wherein the two-stage thermosetting adhesive layer 730 has a first adhesive surface 732 and a second adhesive surface 734. At least part of the first adhesive surface 732 is bonded to the second bottom surface 726, and part of the second adhesive surface 734 is bonded to the first upper surface 712, so that the second chip 720 is adhered to the first upper surface 712 of the first chip 710. The first adhesive surface 732 is substantially parallel to the second adhesive surface 734, and the two-stage thermosetting adhesive layer 730 has a tapered edge E′.

In addition, the circuit substrate 740 has an upper surface 742 of the substrate and a bottom surface 744 of the substrate, and the first chip 710 is disposed on the upper surface 742 of the substrate, and the first chip 710 and the second chip 720 are electrically connected to the circuit substrate 740, respectively.

In the fifth embodiment, the first chip 710 includes a plurality of first bonding pads 718 located on the first bottom surface 716, and the second chip 720 includes a plurality of second bonding pads 728 located on the second upper surface 722. In addition, the chip package structure 700 further includes a plurality of bonding wires 750 and a plurality of solder bumps 760. At least one of the second bonding pads 728 is electrically connected to the upper surface 742 of the substrate through at least one of the bonding wires 750, and each of the first bonding pads 718 is electrically connected to the upper surface 742 of the substrate through at least one of the solder bumps 760. Moreover, the chip package structure 700 further includes an encapsulant 770 which encapsulates at least the first chip 710, the second chip 720, the bonding wires and the solder bumps 760.

It can be learned from the above that, the main difference between the fifth embodiment and the third embodiment is that, the first chip 710 adjacent to the circuit substrate 740 is electrically connected with the circuit substrate 740 by flip chip bonding technology. It should be noted that, the two-stage thermosetting adhesive layer 730 of the chip package structure 700 is the same as that described in the first embodiment, therefore, the detail is omitted here. In addition, in the fifth embodiment, the two-stage thermosetting adhesive layer 730 can also have a circuit raised portion (not shown), which surrounds the second side surface 724 and is bonded to the second side surface 724. And, a top surface (not shown) of the ringlike protruding portion adjacent to the second side surface 724 is substantially perpendicular to the second side surface 724. The formation of the ringlike protruding portion has been described in the second embodiment, and thus the detail is omitted here.

### The Sixth Embodiment

Referring to FIG. 8, FIG. 8 is a schematic cross-sectional diagram of a chip package structure according to the sixth embodiment of the present invention. The main difference between the sixth embodiment and the fifth embodiment is that: the width d1 of the first chip 810 of the chip package structure 800 is greater than the width d2 of the second chip 820. Moreover, in the sixth embodiment, the two-stage thermosetting adhesive layer 830 can also have a ringlike protruding portion 836, and, the formation and the figuration are the same as described in the second embodiment, therefore the detail is omitted here. However, in the sixth embodiment, if the two-stage thermosetting adhesive layer 830 has a ringlike protruding portion 836, the ringlike protruding portion 836 surrounds the first side surface 814 of the first chip 810, and the first side surface 814 is bonded to the ringlike protruding portion 836 while a top surface 836a of the ringlike protruding portion 836 adjacent to the first side surface 814 is substantially perpendicular to the first side surface 814.

In summary, the chip package structure of the present invention has at least the following advantages:

First, as the two-stage thermosetting adhesive layer of the chip package structure of the present invention can be pre-cured into solid or gel B-stage thermosetting adhesive layer by UV radiation or heating, in the subsequent fabricating processes to compress the chip onto the circuit substrate or compress the chip onto another chip, the two-stage thermosetting adhesive layer will not overflow to other areas of the circuit substrate or another chip, so as to protect the area where the circuit substrate or another chip is electrically connected with the bonding wires from being contaminated.

Second, as the two-stage thermosetting adhesive layer of the chip package structure of the present invention can be pre-cured into the B-stage thermosetting adhesive layer which has no adhesion at room temperature, the circuit substrate or the chip with spread of the two-stage thermosetting adhesive layer can be shipped or stored in stack.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A chip package structure, comprising:
a first chip, having a first upper surface, a first side surface, and a first bottom surface;
a circuit substrate, having an upper surface and a bottom surface, wherein the first chip is electrically connected to the circuit substrate; and
a two-stage thermosetting adhesive layer, located on the upper surface of the substrate and having a first adhesive surface and a second adhesive surface, wherein part of the first adhesive surface is bonded to the first bottom surface and the second adhesive surface is bonded to the upper surface of the substrate such that the first chip is adhered to the upper surface of the substrate, and the first adhesive surface is substantially parallel to the second adhesive surface and the two-stage thermosetting adhesive layer has a tapered edge.

2. The chip package structure as claimed in claim 1, wherein the first chip comprises a plurality of bonding pads located on the first upper surface.

3. The chip package structure as claimed in claim 2 further comprising a plurality of bonding wires, wherein at least one of the bonding pads is electrically connected with the upper surface of the substrate through at least one of the bonding wires.

4. The chip package structure as claimed in claim 3 further comprising an encapsulant for encapsulating the first chip and the bonding wires.

5. The chip package structure as claimed in claim 1 further comprising:
a second chip, having a second upper surface, a second bottom surface and a plurality of bonding pads located on the second upper surface, wherein the second chip is electrically connected to the circuit substrate; and
an adhesive layer, located between the first chip and the second chip, wherein the second bottom surface of the second chip is bonded to the first upper surface of the first chip by the adhesive layer.

6. The chip package structure as claimed in claim 5, wherein a material of the adhesive layer is the same as that of the two-stage thermosetting adhesive layer.

7. The chip package structure as claimed in claim 5 further comprising a plurality of bonding wires, wherein at least one of the bonding pads is electrically connected with the upper surface of the substrate through at least one of the bonding wires.

8. The chip package structure as claimed in claim 7 further comprising an encapsulant for encapsulating the first chip, the second chip and the bonding wires.

9. The chip package structure as claimed in claim 1, wherein the circuit substrate has a through hole.

10. The chip package structure as claimed in claim 9, wherein the two-stage thermosetting adhesive layer is located in a surrounding area of the through hole.

11. The chip package structure as claimed in claim 9, wherein the first chip comprises a plurality of bonding pads located on the first bottom surface, and the bonding pads are exposed through the through hole.

12. The chip package structure as claimed in claim 1 further comprising a plurality of bonding wires, wherein each bonding pad is electrically connected with the bottom surface of the substrate through at least one of the bonding wires and the bonding wires pass through the through hole.

13. The chip package structure as claimed in claim 12 further comprising an encapsulant filled the through hole to capsulate the first chip and the bonding wires.

14. The chip package structure as claimed in claim 1, wherein the two-stage thermosetting adhesive layer further comprises a ringlike protruding portion surrounding the first side surface, and the first side surface is bonded to the ring-like protruding portion while a top surface of the ringlike protruding portion adjacent to the first side surface is substantially perpendicular to the first side surface.

15. The chip package structure as claimed in claim 1, wherein the two-stage thermosetting adhesive layer comprises a solvent type two-stage thermosetting adhesive layer or a non-solvent type two-stage thermosetting adhesive layer.

16. The chip package structure as claimed in claim 1, wherein a material of the two-stage thermosetting adhesive layer comprises polyimide, benzocyclobutene (BCB), or polyquinolin.

17. The chip package structure as claimed in claim 1, wherein the two-stage thermosetting adhesive layer comprises an UV-curing type two-stage thermosetting adhesive layer or a thermal-curing type two-stage thermosetting adhesive layer.

18. A chip package structure, comprising:
a first chip, having a first upper surface, a first side surface, and a first bottom surface;
a second chip, having a second upper surface, a second side surface, and a second bottom surface;
a two-stage thermosetting adhesive layer, located between the first chip and the second chip, wherein the two-stage thermosetting adhesive layer has a first adhesive surface and a second adhesive surface, at least part of the first adhesive surface is bonded to the second bottom surface and at least part of the second adhesive surface is bonded to the first upper surface such that the second chip is adhered to the upper surface of the first chip, and the first adhesive surface is substantially parallel to the second adhesive surface and the two-stage thermosetting adhesive layer has a tapered edge; and
a circuit substrate, having an upper surface and a bottom surface, wherein the first chip is disposed on the upper surface of the substrate, and the first chip and the second chip are electrically connected to the circuit substrate, respectively.

19. The chip package structure as claimed in claim 18 further comprising an adhesive layer, disposed between the first chip and the circuit substrate, wherein the first bottom surface of the first chip is bonded to the upper surface of the substrate of the circuit substrate by the adhesive layer.

20. The chip package structure as claimed in claim 18, wherein the first chip comprises a plurality of first bonding pads located on the first upper surface, and the second chip comprises a plurality of second bonding pads located on the second upper surface.

21. The chip package structure as claimed in claim 20 further comprising:
a plurality of first bonding wires, at least one of the first bonding pads is electrically connected with the upper surface of the substrate through at least one of the first bonding wires; and
a plurality of second bonding wires, at least one of the second bonding pads is electrically connected with the upper surface of the substrate through at least one of the second bonding wires.

22. The chip package structure as claimed in claim 21 further comprising an encapsulant for encapsulating the first and the second chips, the first and the second bonding wires.

23. The chip package structure as claimed in claim 18, wherein the first chip comprises a plurality of first bonding pads located on the first bottom surface, and the second chip comprises a plurality of second bonding pads located on the second upper surface.

24. The chip package structure as claimed in claim 23 further comprising:
a plurality of bonding wires, at least one of the second bonding pads is electrically connected with the upper surface of the substrate through at least one of the bonding wires; and
a plurality of solder bumps, wherein each first bonding pad is electrically connected with the upper surface of the substrate through one of the solder bumps.

25. The chip package structure as claimed in claim 24 further comprising an encapsulant for encapsulating the first chip, the second chip, the bonding wires and the solder bumps.

26. The chip package structure as claimed in claim 18, wherein the two-stage thermosetting adhesive layer further comprises a ringlike protruding portion, surrounding the first side surface, and the first side surface is bonded to the ring-like protruding portion while a top surface of the ringlike protruding portion adjacent to the first side surface is substantially perpendicular to the first side surface.

27. The chip package structure as claimed in claim 18, wherein the two-stage thermosetting adhesive layer further comprises a ringlike protruding portion, surrounding the second side surface, and the second side surface is bonded to the ringlike protruding portion while a top surface of the ringlike protruding portion adjacent to the second side surface is substantially perpendicular to the second side surface.

28. The chip package structure as claimed in claim 18, wherein the two-stage thermosetting adhesive layer comprises a solvent type two-stage thermosetting adhesive layer or a non-solvent type two-stage thermosetting adhesive layer.

29. The chip package structure as claimed in claim 18, wherein a material of the two-stage thermosetting adhesive layer comprises polyimide, benzocyclobutene (BCB), or polyquinolin.

30. The chip package structure as claimed in claim 18, wherein the two-stage thermosetting adhesive layer comprises an UV-curing type two-stage thermosetting adhesive layer or a thermal-curing type two-stage thermosetting adhesive layer.
